(19) United States
(12) Patent Application Publication
(10) Pub. No.: US 2025/0258430 A1
(43) Pub. Date: Aug. 14, 2025

(54) PHOTOSENSITIVE RESIN COMPOSITION, PHOTOSENSITIVE ELEMENT, PRINTED WIRING BOARD, AND METHOD FOR PRODUCING PRINTED WIRING BOARD

(71) Applicant: Resonac Corporation, Tokyo (JP)

(72) Inventors: Nobuhito KOMURO, Tokyo (JP); Yuta DAIJIMA, Tokyo (JP)

(21) Appl. No.: 18/859,679

(22) PCT Filed: Oct. 5, 2022
(86) PCT No.: PCT/JP2022/037335

§ 371 Date: Oct. 24, 2024

(51) Int. Cl. G03F 7/033; G03F 7/031; G03F 7/075

(52) U.S. Cl. CPC G03F 7/033; G03F 7/031; G03F 7/0755

(57) ABSTRACT

The present disclosure relates to a photosensitive resin composition for a permanent resist, containing: an acid-modified vinyl group-containing resin (A), an epoxy compound (B), a photopolymerization initiator (C), a photopolymerizable compound (D), and an inorganic filler (F), in which an equivalent ratio of an epoxy group contained in the epoxy compound (B) to a carboxy group contained in the acid-modified vinyl group-containing resin (A) is 1.25 to 7.5, and the inorganic filler (F) includes a silica filler having a vinyl group derived from a vinyl silane compound.

### TECHNICAL FIELD

The present disclosure relates to a photosensitive resin composition for a permanent resist, a photosensitive element, a printed wiring board, and a method for producing a printed wiring board.

### BACKGROUND ART

In the field of a printed wiring board, a permanent resist is formed on the printed wiring board. The permanent resist has a function of preventing the corrosion of a conductor layer or retaining an electrical insulating property between the conductor layers when the printed wiring board is used. Recently, in a step of mounting a semiconductor element on the printed wiring board via solder by flip-chip packaging, wire bonding packaging, and the like, the permanent resist has a function as a solder resist film that prevents the solder from being attached to an unnecessary portion of the conductor layer of the printed wiring board.

In the related art, the permanent resist is produced by a screen printing method using a thermosetting resin composition or a photography using a photosensitive resin composition. For example, in a flexible wiring board using a packaging method such as flip chip (FC), tape automated bonding (TAB), and chip on film (COF), a thermosetting resin paste is screen-printed except for an IC chip, an electronic part or a liquid crystal display (LCD) panel, and a connecting wiring pattern portion, and thermally cured to form a permanent resist (for example, refer to Patent Literature 1).

In a semiconductor package substrate such as a ball grid array (BGA) and a chip scale package (CSP) mounted on an electronic part, (1) in order to mount a semiconductor element on the semiconductor package substrate via solder by flip-chip packaging, (2) in order to join the semiconductor element and the semiconductor package substrate by wire bonding, or (3) in order to join the semiconductor package substrate onto a motherboard substrate by solder, it is necessary to remove the permanent resist of the joining portion. In the image formation of the permanent resist, a photography of applying and drying a photosensitive resin composition, and then, selectively curing the photosensitive resin composition by the irradiation of an active ray such as an ultraviolet ray, and developing and removing only an unirradiated portion to form an image is used. Since the photography is suitable for mass production due to excellent workability thereof, in the industry of an electronic material, the photography is widely used for the image formation of a photosensitive material (for example, refer to Patent Literature 2).

### CITATION LIST

### Patent Literature

Patent Literature 1: JP 2003-198105 A
Patent Literature 2: JP H11-240930 A

### SUMMARY OF INVENTION

### Technical Problem

On the other hand, in the permanent resist formed from the photosensitive resin composition of the related art, a crack may occur in the permanent resist under a severe environment such as a high temperature, and there is a demand for a photosensitive resin composition capable of forming a permanent resist excellent in crack resistance. In addition, when forming the permanent resist by using the photosensitive resin composition of the related art, a resist residue may be generated after developing, which may cause a fatal defect when performing bump connection with a chip, and there is a demand for a photosensitive resin composition excellent in a developing property.

Therefore, an object of the present disclosure is to provide a photosensitive resin composition for a permanent resist that is capable of forming a permanent resist excellent in crack resistance, and is excellent in a developing property, and a photosensitive element, a printed wiring board, and a method for producing a printed wiring board, using the photosensitive resin composition.

### Solution to Problem

Some aspects of the present disclosure provide [1] to [9] described below.

[1] A photosensitive resin composition for a permanent resist, containing: an acid-modified vinyl group-containing resin (A); an epoxy compound (B); a photopolymerization initiator (C); a photopolymerizable compound (D); and an inorganic filler (F), in which an equivalent ratio of an epoxy group contained in the epoxy compound (B) to a carboxy group contained in the acid-modified vinyl group-containing resin (A) is 1.25 to 7.50, and the inorganic filler (F) includes a silica filler having a vinyl group derived from a vinyl silane compound.
[2] The photosensitive resin composition according to [1] described above, in which the equivalent ratio is 2.00 to 7.50.
[3] The photosensitive resin composition according to [1] described above, in which the equivalent ratio is 2.50 to 7.50.
[4] The photosensitive resin composition according to any one of [1] to described above, further containing a pigment (E).
[5] A photosensitive element, including: a support film; and a photosensitive layer formed on the support film, in which the photosensitive layer contains the photosensitive resin composition according to any one of [1] to [4] described above.
[6] A printed wiring board, including a permanent resist including a cured product of the photosensitive resin composition according to any one of [1] to [4] described above.
[7] The printed wiring board according to [6] described above, in which a thickness of the permanent resist is 10 to 50 μm.
[8] A method for producing a printed wiring board, including: a step of forming a photosensitive layer on a substrate by using the photosensitive resin composition according to any one of [1] to [4] described above; a step of exposing and developing the photosensitive layer to form a resist pattern; and a step of curing the resist pattern to form a permanent resist.
[9] A method for producing a printed wiring board, including: a step of forming a photosensitive layer on a substrate by using the photosensitive element according to [5] described above; a step of exposing and developing the photosensitive layer to form a resist pattern; and a step of curing the resist pattern to form a permanent resist.

### Advantageous Effects of Invention

According to the present disclosure, it is possible to provide the photosensitive resin composition for a permanent resist that is capable of forming the permanent resist excellent in the crack resistance, and is excellent in the developing property, and the photosensitive element, the printed wiring board, and the method for producing a printed wiring board, using the photosensitive resin composition.

### BRIEF DESCRIPTION OF DRAWINGS

FIG. 1 is a cross-sectional view schematically illustrating a photosensitive element according to the present embodiment.

### DESCRIPTION OF EMBODIMENTS

Hereinafter, one embodiment of the present disclosure will be described in detail, but the present disclosure is not limited thereto. In the following embodiment, constituents (also including element steps and the like) are not necessarily essential except when particularly stated or when considered as apparently essential in principle. The same applies to numerical values and ranges thereof, which are not to be construed as unduly limiting the present disclosure.

In the present disclosure, the term “layer” includes not only a structure in which a layer is formed on the entire surface but also a structure in which a layer is formed on a part of the surface when observed as a plan view. In the present disclosure, the term “step” includes not only an independent step but also a step that is not explicitly distinguishable from other steps insofar as a desired function of the step is attained. In the present disclosure, a numerical range represented by using “to” indicates a range including numerical values described before and after “to” as the minimum value and the maximum value, respectively. In numerical ranges described in stages in the present disclosure, the upper limit value or the lower limit value of a numerical range in a certain stage may be replaced with the upper limit value or the lower limit value of a numerical range in the other stage. In addition, in the numerical range described in the present disclosure, the upper limit value or the lower limit value of the numerical range may be replaced with values described in Examples. In the present disclosure, “A or B” may include either A or B, or may include both thereof. Only one type of materials exemplified below can be used alone, or two or more types thereof may be used in combination, unless otherwise specified. In the present disclosure, in a case where there are a plurality of substances corresponding to each component in a composition, the content of each component in the composition indicates the total amount of the plurality of substances in the composition, unless otherwise specified.

In the present disclosure, a “solid content” indicates a non-volatile content excluding a volatile substance such as water and a diluent contained in a photosensitive resin composition, and indicates a component that remains without being evaporated or volatilized when the resin composition is dried, and also includes a component in the form of a liquid, syrup, or a wax at a room temperature (25° C., the same applies below).

### [Photosensitive Resin Composition]

A photosensitive resin composition according to the present embodiment contains an acid-modified vinyl group-containing resin (A), an epoxy compound (B), a photopolymerization initiator (C), a photopolymerizable compound (D), and an inorganic filler (F), an equivalent ratio (an equivalent ratio of epoxy group/carboxy group, a molar ratio) of an epoxy group contained in the epoxy compound (B) to a carboxy group contained in the acid-modified vinyl group-containing resin (A) is 1.25 to 7.50, and the inorganic filler (F) includes a silica filler having a vinyl group derived from a vinyl silane compound. The photosensitive resin composition according to the present embodiment is a negative photosensitive resin composition, and a cured product of the photosensitive resin composition can be used as a permanent resist. The present inventors have found that in a case where the equivalent ratio of epoxy group/carboxy group is 1.25 or more, since there are more epoxy groups derived from the epoxy compound than the carboxy groups derived from the acid-modified vinyl group-containing resin, which easily makes the elasticity of the permanent resist to be formed excellent, it is possible to improve the crack resistance of the permanent resist, but in accordance with an increase in the equivalent ratio of epoxy group/carboxy group, there is a tendency that the solubility of the cured product to be formed to a developer decreases, and a developing property decreases, found that since the silica filler having a vinyl group derived from a vinyl silane compound is easily developed by being bonded to a functional group such as a vinyl group contained in the acid-modified vinyl group-containing resin, the photopolymerizable compound, and the like in the photosensitive resin composition, compared to other silica fillers, by using the silica filler having a vinyl group derived from a vinyl silane compound in combination as the inorganic filler, it is possible to suppress a decrease in the solubility of the cured product to be formed to the developer, and improve the developing property even in a case where the equivalent ratio of epoxy group/carboxy group is high, and completed the present invention.

The photosensitive resin composition according to the present embodiment is capable of forming the permanent resist excellent in the crack resistance, and reducing the generation of a residue after developing, thereby being also excellent in the developing property. In addition, the photosensitive resin composition according to the present embodiment is excellent in fluidity and is capable of forming the permanent resist that is excellent in adhesiveness to a copper substrate. Further, the photosensitive resin composition according to the present embodiment is also excellent in performance required for the photosensitive resin composition used to produce a printed wiring board, for example, resolution, an electrical insulating property, solder heat resistance, solvent resistance, acid resistance, and alkali resistance. Hereinafter, each component contained in the photosensitive resin composition according to the present embodiment will be described in detail.

### <Component (A): Acid-Modified Vinyl Group-Containing Resin>

The photosensitive resin composition according to the present embodiment contains the acid-modified vinyl group-containing resin as a component (A). The acid-modified vinyl group-containing resin is not particularly limited insofar as the acid-modified vinyl group-containing resin has a vinyl bond, which is a photopolymerizable ethylenically unsaturated bond, and an alkali-soluble acidic group.

Examples of a group having an ethylenically unsaturated bond in the component (A) include a vinyl group, an allyl group, a propargyl group, a butenyl group, an ethynyl group, a phenyl ethynyl group, a maleimide group, a nadi-imide group, and a (meth)acryloyl group. Among them, from the viewpoint of reactivity and the resolution, the group may be the (meth)acryloyl group. Examples of the acidic group in the component (A) include a carboxy group, a sulfo group, and a phenolic hydroxyl group. Among them, from the viewpoint of the resolution, the acidic group may be the carboxy group.

The component (A) may be an acid-modified vinyl group-containing epoxy derivative obtained by causing a resin (A′) (hereinafter, may be referred to as a “component (A′)”) obtained by a reaction between an epoxy resin (a) (hereinafter, may be referred to as a “component (a)”) and an ethylenically unsaturated group-containing organic acid (b) (hereinafter, may be referred to as a “component (b)”) to react with a saturated group or an unsaturated group-containing polybasic anhydride (c) (hereinafter, may be referred to as a “component (c)”).

Examples of the acid-modified vinyl group-containing epoxy derivative include acid-modified epoxy (meth)acrylate. The acid-modified epoxy (meth)acrylate is a resin in which epoxy (meth)acrylate, which is a reactant of the component (a) and the component (b), is subjected to acid modification with the component (c). As the acid-modified epoxy (meth)acrylate, for example, an addition reactant in which a saturated or unsaturated polybasic anhydride is added to an esterified product obtained by a reaction between an epoxy resin and a vinyl group-containing monocarboxylic acid can be used.

Examples of the component (A) include an acid-modified vinyl group-containing resin (A1) (hereinafter, may be referred to as a “component (A1)”) obtained by using a bisphenol novolac-type epoxy resin (a1) (hereinafter, may be referred to as an “epoxy resin (a1)”) as the component (a), and an acid-modified vinyl group-containing resin (A2) (hereinafter, may be referred to as a “component (A2)”) obtained by using an epoxy resin (a2) other than the epoxy resin (a1) (hereinafter, may be referred to as an “epoxy resin (a2)”) as the component (a). Only one type of the component (A) can be used alone, or two or more types thereof can be used in combination.

(Epoxy Resin (a1))

Examples of the epoxy resin (a1) include an epoxy resin having a structural unit represented by Formula (I) or (II) described below. The epoxy resin (a1) may be the epoxy resin having a structural unit represented by Formula (I).

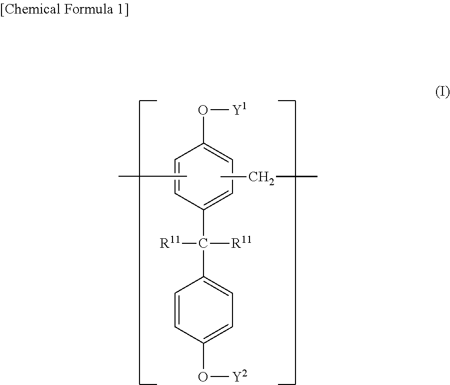

In Formula (I), R¹¹ indicates a hydrogen atom or a methyl group, and a plurality of R¹¹'s may be the same or different. Y¹ and Y² each independently indicate a hydrogen atom or a glycidyl group, and at least one of Y¹ and Y² is a glycidyl group.

From the viewpoint of improving the resolution, R¹¹ may be a hydrogen atom, and Y¹ and Y² may be a glycidyl group.

The number of structural units represented by Formula (I) in the epoxy resin (a1) is 1 or more, and may be 10 to 100, 15 to 80, or 15 to 70. In a case where the number of structural units is in the range described above, heat resistance and an electrical insulating property are easily improved. Here, the number of structural units indicates an integer value in a single molecule, and indicates a rational number that is an average value in a cluster of a plurality of types of molecules (the same applies below).

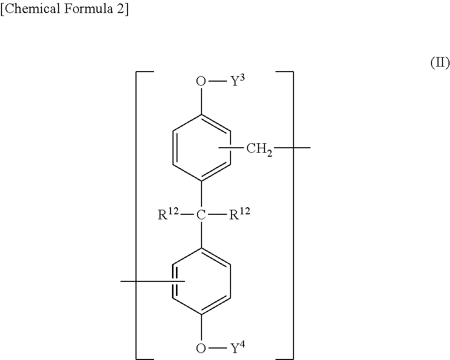

In Formula (II), R¹² indicates a hydrogen atom or a methyl group, and a plurality of R¹²'s may be the same or different. Y³ and Y⁴ each independently indicate a hydrogen atom or a glycidyl group, and at least one of Y³ and Y⁴ is a glycidyl group.

From the viewpoint of improving the resolution, R¹² may be a hydrogen atom, and Y³ and Y⁴ may be a glycidyl group.

The number of structural units represented by Formula (II) in the epoxy resin (a1) is 1 or more, and may be 10 to 100, 15 to 80, or 15 to 70. In a case where the number of structural units is in the range described above, the heat resistance and the electrical insulating property are easily improved.

An epoxy resin in which in Formula (II), R¹² is a hydrogen atom, and Y³ and Y⁴ are a glycidyl group is commercially available as EXA-7376 Series (manufactured by DIC Corporation, Product Name). An epoxy resin in which in Formula (II), R¹² is a methyl group, and Y³ and Y⁴ are a glycidyl group is commercially available as EPON SU8 Series (manufactured by Mitsubishi Chemical Corporation, Product Name).

(Epoxy Resin (a2))

The epoxy resin (a2) is not particularly limited insofar as the epoxy resin (a2) is an epoxy resin different from the epoxy resin (a1), and may be at least one type selected from the group consisting of a novolac-type epoxy resin, a bisphenol A-type epoxy resin, a bisphenol F-type epoxy resin, a triphenol methane-type epoxy resin, and a biphenyl-type epoxy resin.

Examples of the epoxy resin (a2) include a bisphenol A-type epoxy resin or a bisphenol F-type epoxy resin having a structural unit represented by Formula (III) described below. Examples of the epoxy resin having such a structural unit include a bisphenol A-type epoxy resin or a bisphenol F-type epoxy resin represented by Formula (III′) described below.

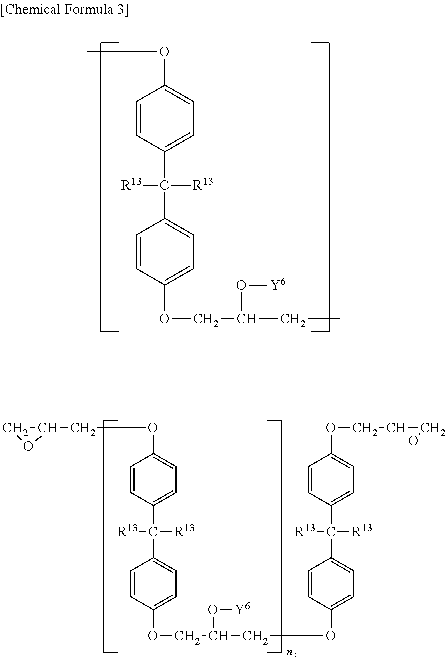

In Formulae (III) and (III′), R¹³ indicates a hydrogen atom or a methyl group, a plurality of R¹³'s may be the same or different, and Y⁵ indicates a hydrogen atom or a glycidyl group. In Formula (III′), n₂ indicates a number of 1 or more, and in a case where n₂ is 2 or more, a plurality of Y⁵'s may be the same or different, and at least one Y⁵ is a glycidyl group.

From the viewpoint of improving the resolution, R¹³ may be a hydrogen atom. From the viewpoint of further improving the crack resistance, Y⁵ may be a glycidyl group. n₂ indicates 1 or more, and may be 10 to 100, 10 to 80, or 15 to 60. In a case where n₂ is in the range described above, the linearity of the contour of the resist pattern and the heat resistance are easily improved.

A bisphenol A-type epoxy resin or a bisphenol F-type epoxy resin in which in Formula (III), Y⁵ is a glycidyl group, for example, can be obtained by a reaction between a hydroxyl group (—OY⁵) of a bisphenol A-type epoxy resin or a bisphenol F-type epoxy resin in which in Formula (III), Y⁵ is a hydrogen atom, and epichlorohydrin.

In order to accelerate the reaction between the hydroxyl group and the epichlorohydrin, the reaction may be performed in a polar organic solvent such as dimethyl formamide, dimethyl acetamide, and dimethyl sulfoxide, at a reaction temperature of 50 to 120° C. in the presence of an alkali metal hydroxide. In a case where the reaction temperature is in the range described above, it is possible to suppress a side reaction without excessively decelerating the reaction.

As the bisphenol A-type epoxy resin or the bisphenol F-type epoxy resin represented by Formula (III′), for example, jER807, jER815, jER825, jER827, jER828, jER834, jER1001, jER1004, jER1007, and jER1009 (all are manufactured by Mitsubishi Chemical Corporation, Product Name), DER-330, DER-301, and DER-361 (all are manufactured by The Dow Chemical Company, Product Name), YD-8125, YDF-170, YDF-175S, YDF-2001, YDF-2004, and YDF-8170 (all are manufactured by NIPPON STEEL Chemical & Material Co., Ltd., Product Name) are commercially available.

### (Ethylenically Unsaturated Group-Containing Organic Acid (b))

Examples of the component (b) include an acrylic acid; an acrylic acid derivative such as a dimer of an acrylic acid, a methacrylic acid, a P-furfuryl acrylic acid, a P-styryl acrylic acid, a cinnamic acid, a crotonic acid, and an a-cyanocinnamic acid; a half ester compound that is a reaction product of hydroxyl group-containing acrylate and a dibasic anhydride; and a half ester compound that is a reaction product of vinyl group-containing monoglycidyl ether or vinyl group-containing monoglycidyl ester and a dibasic anhydride. Only one type of the component (b) can be used alone, or two or more types thereof can be used in combination.

The half ester compound, for example, is obtained by a reaction between hydroxyl group-containing acrylate, vinyl group-containing monoglycidyl ether, or vinyl group-containing monoglycidyl ester and a dibasic anhydride at an equal molar ratio.

Examples of the hydroxyl group-containing acrylate, the vinyl group-containing monoglycidyl ether, and the vinyl group-containing monoglycidyl ester include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylol propane diacrylate, trimethylol propane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic anhydride include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride.

The reaction between the component (a) and the component (b) may be performed at a ratio in which the component (b) is 0.6 to 1.05 equivalents with respect to 1 equivalent of the epoxy group of the component (a), or may be performed at a ratio in which the component (b) is 0.8 to 1.0 equivalents with respect to 1 equivalent of the epoxy group of the component (a). By performing the reaction at such a ratio, photopolymerizability is improved, that is, photosensitivity increases, and the resolution is easily improved.

The reaction between the component (a) and the component (b) can be performed by dissolving the components in an organic solvent. Examples of the organic solvent include ketones such as methyl ethyl ketone and cyclohexanone; aromatic hydrocarbon such as toluene, xylene, and tetramethyl benzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of the organic solvent may be used alone, or two or more types thereof may be used in combination.

In order to accelerate the reaction between the component (a) and the component (b), a catalyst may be used. Examples of the catalyst include triethyl amine, benzyl methyl amine, methyl triethyl ammonium chloride, benzyl trimethyl ammonium chloride, benzyl trimethyl ammonium bromide, benzyl trimethyl ammonium iodide, and triphenyl phosphine. Only one type of the catalyst may be used alone, or two or more types thereof may be used in combination.

From the viewpoint of accelerating the reaction between the component (a) and the component (b), the used amount of the catalyst may be 0.01 to 10 parts by mass, 0.05 to 2 parts by mass, or 0.1 to 1 parts by mass, with respect to a total of 100 parts by mass of the component (a) and the component (b).

In order to prevent polymerization during the reaction, a polymerization inhibitor may be used. Examples of the polymerization inhibitor include hydroquinone, methyl hydroquinone, hydroquinone monomethyl ether, catechol, and pyrogallol. Only one type of the polymerization inhibitor may be used alone, or two or more types thereof may be used in combination. The used amount of the polymerization inhibitor, from the viewpoint of storage stability, may be 0.01 to 1 parts by mass, 0.02 to 0.8 parts by mass, or 0.04 to 0.5 parts by mass, with respect to a total of 100 parts by mass of the component (a) and the component (b).

The temperature of the reaction between the component (a) and the component (b), from the viewpoint of productivity, may be 60 to 150° C., 80 to 120° C., or 90 to 110° C.

It is assumed that the component (A′) obtained by the reaction between the component (a) and the component (b) has a hydroxyl group formed by a ring-opening addition reaction between the epoxy group of the component (a) and the carboxy group of the component (b). It is assumed that by causing the component (A′) to further react with the component (c), an acid-modified vinyl group-containing epoxy resin is obtained in which the hydroxyl group of the component (A′) (also including a hydroxyl group originally present in the component (a)) and the acid anhydride group of the component (c) are half-esterified.

### (Polybasic Anhydride (c))

Examples of the component (c) include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride. Among them, from the viewpoint of the resolution, the component (c) may be the tetrahydrophthalic anhydride. Only one type of the component (c) may be used alone, or two or more types thereof may be used in combination.

The temperature of the reaction between the component (A′) and the component (c), from the viewpoint of the productivity, may be 50 to 150° C., 60 to 120° C., or 70 to 100° C.

As necessary, as the component (a), for example, a hydrogenated bisphenol A-type epoxy resin may be used together, or a styrene-maleic acid-based resin such as a hydroxyethyl (meth)acrylate modified product of a styrene-maleic anhydride copolymer may be used together.

In the reaction between the component (A′) and the component (c), for example, by causing 0.1 to 1.0 equivalents of the component (c) to react with 1 equivalent of the hydroxyl group in the component (A′), it is possible to adjust the acid value of the component (A).

The acid value of the component (A) may be 30 to 150 mgKOH/g, or 40 to 120 mgKOH/g. In a case where the acid value of the component (A) is 30 mgKOH/g or more, there is a tendency that it is excellent in the solubility of the photosensitive resin composition to a diluted alkaline solution. From the same viewpoint, the acid value of the component (A) may be 35 mgKOH/g or more, or 40 mgKOH/g or more. In a case where the acid value of the component (A) is 150 mgKOH/g or less, the electrical property of the permanent resist is easily improved. From the same viewpoint, the acid value of the component (A) may be 120 mgKOH/g or less, 100 mgKOH/g or less, 90 mgKOH/g or less, 80 mgKOH/g or less, 70 mgKOH/g or less, 60 mgKOH/g or less, or 50 mgKOH/g or less.

Here, the acid value can be measured by the following method. First, approximately 1 g of a solution of the component (A) is weighed. After that, 30 g of acetone is added to such a solution, and homogeneously mixed. A suitable amount of phenolphthalein, which is an indicator, is added to the solution after mixing. Titration is performed by using 0.1 N of a KOH aqueous solution. A titer of KOH aqueous solution is obtained, and an acid value is calculated by the following expression.

$$Acid Value = 10 \times Vf \times 56.1 / ( Wp \times I )$$

In the expression, Vf indicates the titer (mL) of 0.1 N of the KOH aqueous solution, Wp indicates the measured mass (g) of the solution of the component (A), and I indicates the measured ratio (% by mass) of a non-volatile content in the solution of the component (A).

The weight average molecular weight (Mw) of the component (A), from the viewpoint of the resolution, the heat resistance, and the electrical insulating property, may be 3000 to 30000, 4000 to 25000, or 5000 to 18000. Here, Mw can be measured by a gel permeation chromatography (GPC) method. For Mw, for example, a value obtained by measurement in the following GPC condition, and conversion using a calibration curve of standard polystyrene can be set as Mw. The calibration curve can be created by using a five-sample set (“PStQuick MP-H” and “PStQuick B”, manufactured by Tosoh Corporation) as standard polystyrene.

### (GPC Condition)

GPC Equipment: high-speed GPC equipment “HCL-8320GPC” (manufactured by Tosoh Corporation)
Detector: a differential refractometer or a UV detector (manufactured by Tosoh Corporation)
Column: column TSKgel SuperMultipore HZ-H (Column Length: 15 cm, Column Inner Diameter: 4.6 mm) (manufactured by Tosoh Corporation)
Eluent: tetrahydrofuran (THF)
Measurement Temperature: 40° C.
Flow Rate: 0.35 mL/minute
Sample Concentration: 10 mg/THF 5 mL
Injection Amount: 20 μL

The content of the component (A) in the photosensitive resin composition, from the viewpoint of improving the heat resistance, the electrical property, and the chemical resistance of the permanent resist, may be 10% by mass or more, 15% by mass or more, or 20% by mass or more, and may be 80% by mass or less, 70% by mass or less, 50% by mass or less, or 40% by mass or less, on the basis of the total solid content of the photosensitive resin composition. From the same viewpoint, the content of the component (A) may be 10 to 80% by mass, 15 to 70% by mass, 20 to 50% by mass, or 20 to 40% by mass.

In the case of using the component (A1) and the component (A2) in combination as the component (A), the total content of the component (A1) and the component (A2) in the component (A), from the viewpoint of improving the solder heat resistance, may be 80 to 100% by mass, 90 to 100% by mass, 95 to 100% by mass, or 100% by mass, on the basis of the total amount of the component (A). Even in a case where the component (A1) or the component (A2) is used alone, the content can be suitably selected from the range described above.

In the case of using the component (A1) and the component (A2) in combination as the component (A), a mass ratio (A1/A2) thereof, from the viewpoint of improving the solder heat resistance, may be 20/80 to 90/10, 20/80 to 80/20, or 30/70 to 70/30.

### <Component (B): Epoxy Compound>

The photosensitive resin composition according to the present embodiment contains the epoxy compound as a component (B). As the component (B), a compound having two or more epoxy groups can be used, and examples thereof include an epoxy compound that is cured with the carboxy group in the component (A) by heat or an ultraviolet ray. By using the component (B), the photosensitive resin composition according to the present embodiment is capable of forming the permanent resist excellent in the heat resistance, the adhesiveness, and the chemical resistance. Only one type of the component (B) may be used alone, or two or more types thereof may be used in combination.

Examples of the component (B) include a bisphenol A-type epoxy resin, a bisphenol F-type epoxy resin, a hydrogenated bisphenol A-type epoxy resin, a brominated bisphenol A-type epoxy resin, a novolac-type epoxy resin, a bisphenol S-type epoxy resin, a biphenyl-type epoxy resin, a heterocyclic epoxy resin such as triglycidyl isocyanurate, and a bixylenol-type epoxy resin.

The epoxy equivalent of the component (B), from the viewpoint of the crack resistance, may be 100 g/eq or more, 130 g/eq or more, or 150 g/eq or more. The epoxy equivalent of the component (B) may be 450 g/eq or less, 400 g/eq or less, or 380 g/eq or less. The epoxy equivalent of the component (B) may be 100 g/eq to 450 g/eq, 130 g/eq to 400 g/eq, or 150 g/eq to 380 g/eq. The epoxy equivalent can be measured in accordance with JIS K 7236.

The content of the component (B) in the photosensitive resin composition, from the viewpoint of the crack resistance, may be 2% by mass or more, 4% by mass or more, or 6% by mass or more, on the basis of the total solid content of the photosensitive resin composition. The content of the component (B) may be 40% by mass or less, or 35% by mass or less. The content of the component (B) may be 2 to 40% by mass, 4 to 40% by mass, or 6 to 35% by mass.

From the viewpoint of being excellent in the crack resistance and the developing property, the equivalent ratio of the epoxy group contained in the component (B) to the carboxy group contained in the component (A) is 1.25 to 7.50. From the viewpoint of being more excellent in the crack resistance and the developing property, the equivalent ratio may be 1.50 or more, 1.75 or more, 1.95 or more, 2.00 or more, 2.20 or more, 2.40 or more, 2.50 or more, 3.00 or more, 3.50 or more, or 4.00 or more, and may be 7.40 or less, 7.30 or less, 7.20 or less, 7.10 or less, 7.00 or less, 6.75 or less, 6.50 or less, or 6.00 or less. From the same viewpoint, the equivalent ratio may be 2.00 to 7.50, 2.00 to 7.00, 2.50 to 7.00, or 4.00 to 7.00. In a case where the equivalent ratio is 1.25 or more and 7.50 or less, there is a tendency that it is also excellent in the resolution, the solder heat resistance, the solvent resistance, the acid resistance, the alkali resistance, and the electrical insulating property, in addition to the crack resistance and the developing property. That is, for the content of the component (B) in the photosensitive resin composition, the epoxy group contained in the component (B) is 1.25 to 7.50 equivalent, may be 1.50 equivalents or more, 1.75 equivalents or more, 1.95 equivalents or more, 2.00 equivalents or more, 2.20 equivalents or more, 2.40 equivalents or more, 2.50 equivalents or more, 3.00 equivalents or more, 3.50 equivalents or more, or 4.00 equivalents or more, and may be 7.40 equivalents or less, 7.30 equivalents or less, 7.20 equivalents or less, 7.10 equivalents or less, 7.00 equivalents or less, 6.75 equivalents or less, 6.50 equivalents or less, or 6.00 equivalents or less, with respect to 1 equivalent of the carboxy group contained in the component (A).

The equivalent ratio of epoxy group/carboxy group can be calculated by the following expression.

Amount (mmol) of Carboxy Group=Number of Blending Parts of Component(A)×Acid Value (mgKOH/g) of Component(A)/Molecular Weight of KOH

$$Amount ( mmol ) of Epoxy Group = Number of Blending Parts of Component ( B ) / Epoxy Equivalent ( g / eq ) of Component ( B ) \times 1000$$

Equivalent Ratio(Molar Ratio) of Epoxy Group/Carboxy Group=Amount (mmol) of Epoxy Group/Amount (mmol) of Carboxy Group

### <Component (C): Photopolymerization Initiator>

The photosensitive resin composition according to the present embodiment contains the photopolymerization initiator as a component (C). The component (C) is not particularly limited insofar as the component (C) is capable of polymerizing the photopolymerizable compound, which is a component (D). Examples of the component (C) include an alkyl phenone-based photopolymerization initiator, an acyl phosphine oxide-based photopolymerization initiator, a compound having a thioxanthone skeleton, and a titanocene-based photopolymerization initiator. Among them, from the viewpoint of improving the solder heat resistance, the component (C) may be the alkyl phenone-based photopolymerization initiator, the compound having a thioxanthone skeleton, or the acyl phosphine oxide-based photopolymerization initiator. Only one type of the component (C) can be used alone, or two or more types thereof can be used in combination.

Examples of the alkyl phenone-based photopolymerization initiator include benzophenone, N,N,N′,N′-tetraalkyl-4,4′-diaminobenzophenone, 2-benzyl-2-dimethyl amino-1-(4-morpholinophenyl)-butanone-1, 2-methyl-1-[4-(methyl thio)phenyl]-2-morpholino-1-propanone, 4,4′-bis(dimethyl amino)benzophenone (Michler's ketone), 4,4′-bis(diethyl amino)benzophenone, and 4-methoxy-4′-dimethyl aminobenzophenone.

Examples of the acyl phosphine oxide-based photopolymerization initiator include (2,6-dimethoxybenzoyl)-2,4,4-pentyl phosphine oxide, 2,4,6-trimethyl benzoyl diphenyl phosphine oxide, ethyl-2,4,6-trimethyl benzoyl phenyl phosphinate, bis(2,4,6-trimethyl benzoyl)-phenyl phosphine oxide, (2,5-dihydroxyphenyl) diphenyl phosphine oxide, (p-hydroxyphenyl) diphenyl phosphine oxide, bis(p-hydroxyphenyl) phenyl phosphine oxide, tris(p-hydroxyphenyl) phosphine oxide, and bis(2,6-dimethoxybenzoyl)-2,4,4-trimethyl-pentyl phosphine oxide.

Examples of the compound having a thioxanthone skeleton include thioxanthone, 2-chlorothioxanthone, 2-methyl thioxanthone, 2,4-dimethyl thioxanthone, isopropyl thioxanthone, 2,4-dichlorothioxanthone, 2,4-diethyl thioxanthone, isopropyl thioxanthone, 2,4-diisopropyl thioxanthone, and dodecyl thioxanthone.

The content of the component (C) in the photosensitive resin composition is not particularly limited, and may be 0.2 to 15% by mass, 0.4 to 5% by mass, or 0.6 to 1% by mass, on the basis of the total solid content of the photosensitive resin composition. In a case where the content of the component (C) is 0.2% by mass or more, an exposed portion is less likely to be eluted during developing, and in a case where the content is 15% by mass or less, a decrease in the heat resistance is easily suppressed.

### <Component (D): Photopolymerizable Compound>

The photosensitive resin composition according to the present embodiment contains the photopolymerizable compound as a component (D). The component (D) is not particularly limited insofar as the component (D) is a compound having a photopolymerizable functional group. Examples of the photopolymerizable functional group include an ethylenically unsaturated group such as a vinyl group, an allyl group, a propargyl group, a butenyl group, an ethynyl group, a phenyl ethynyl group, a maleimide group, a nadi-imide group, and a (meth)acryloyl group. From the viewpoint of the reactivity, the component (D) may include a compound having a (meth)acryloyl group.

Examples of the component (D) include a hydroxyalkyl (meth)acrylate compound such as 2-hydroxyethyl (meth)acrylate and 2-hydroxypropyl (meth)acrylate; a mono or di(meth)acrylate compound of glycol, such as ethylene glycol, methoxytetraethylene glycol, and polyethylene glycol; a (meth)acryl amide compound such as N,N-dimethyl (meth)acryl amide and N-methylol (meth)acryl amide; an aminoalkyl (meth)acrylate compound such as N,N-dimethyl aminoethyl (meth)acrylate; a polyvalent (meth)acrylate compound of polyhydric alcohol or an ethylene oxide or a propylene oxide adduct thereof, such as hexane diol, trimethylol propane, pentaerythritol, ditrimethylol propane, dipentaerythritol, and tris-hydroxyethyl isocyanurate; a (meth)acrylate compound of an ethylene oxide or propylene oxide adduct of a phenol compound, such as phenoxyethyl (meth)acrylate, and polyethoxydi(meth)acrylate of bisphenol A; a (meth)acrylate compound of glycidyl ether, such as glycerin diglycidyl ether, trimethylol propane triglycidyl ether, and triglycidyl isocyanurate; and melamine (meth)acrylate. Only one type of the component (D) can be used alone, or two or more types thereof can be used in combination.

The content of the component (D) in the photosensitive resin composition may be 0.1 to 10% by mass, 0.5 to 8% by mass, or 2 to 7% by mass, on the basis of the total solid content in the photosensitive resin composition. In a case where the content of the component (D) is 0.1% by mass or more, the exposed portion is less likely to be eluted during developing, and in a case where the content is 10% by mass or less, the heat resistance is easily improved.

### <Component (E): Pigment>

The photosensitive resin composition according to the present embodiment may further contain a pigment as a component (E). As the component (E), a colorant that produces a desired color when hiding wiring can be used. Examples of the component (E) include a known colorant such as phthalocyanine blue, phthalocyanine green, iodine green, diazo yellow, crystal violet, titanium oxide, carbon black, and naphthalene black. Only one type of the component (E) can be used alone, or two or more types thereof can be used in combination.

The content of the component (E), from the viewpoint of further hiding the wiring, may be 2 to 30% by mass, 2.5 to 20% by mass, or 2.5 to 10% by mass, on the basis of the total solid content in the photosensitive resin composition.

### <Component (F): Inorganic Filler>

In order to improve the property of the permanent resist, such as the adhesiveness and hardness, the photosensitive resin composition according to the present embodiment contains the inorganic filler as a component (F). Examples of the component (F) include silica, alumina, zirconia, talc, aluminum hydroxide, calcium carbonate, barium sulfate, calcium sulfate, zinc oxide, magnesium titanate, and carbon. Only one type of the component (F) can be used alone, or two or more types thereof can be used in combination.

The component (F), from the viewpoint of the crack resistance, the developing property, and the resolution, includes a silica filler having a vinyl group derived from a vinyl silane compound (hereinafter, may be referred to as a “vinyl group-containing silica filler”). The vinyl group-containing silica filler can be obtained by performing a surface treatment on silica particles with a vinyl silane compound. The surface treatment, for example, can be performed by adding a solution of the vinyl silane compound to the silica particles and stirring the solution and the particles.

The vinyl silane compound is not particularly limited insofar as the vinyl silane compound is a silane compound having one or more vinyl groups bonded to a silicon atom. In the vinyl silane compound, the number of vinyl groups bonded to the silicon atom may be 2, or may be 3. The vinyl silane compound may have an alkoxy group, an acetoxy group, an alkyl group, and the like, in addition to the vinyl group bonded to the silicon atom. Examples of the vinyl silane compound include vinyl alkoxysilane, and acetoxysilane in which an alkoxy group in the vinyl alkoxysilane is substituted with an acetoxy group.

The vinyl alkoxysilane is not particularly limited insofar as the vinyl alkoxysilane is a silane compound having a vinyl group bonded to a silicon atom and an alkoxy group bonded to a silicon atom. In the vinyl alkoxysilane, the number of alkoxy groups bonded to the silicon atom may be 2, or may be 3. In the vinyl alkoxysilane, in a case where the number of alkoxy groups bonded to the silicon atom is 2 or more, such alkoxy groups may be identical to each other, or may be different from each other. The number of carbon atoms of the alkoxy group bonded to the silicon atom may be 1 to 10, 1 to 6, 1 to 5, 1 to 4, or 1 to 3. The vinyl alkoxysilane may have an alkyl group bonded to the silicon atom. In a case where the vinyl alkoxysilane has the alkyl group bonded to the silicon atom, the number of carbon atoms of the alkyl group may be 1 to 10, 1 to 6, 1 to 5, 1 to 4, or 1 to 3.

Examples of the vinyl alkoxysilane include vinyl trialkoxysilane having three alkoxy groups bonded to a silicon atom, such as vinyl trimethoxysilane, vinyl triethoxysilane, and vinyl triisopropoxysilane, vinyl dialkoxysilane having two alkoxy groups bonded to a silicon atom, such as vinyl dimethoxysilane, vinyl diethoxysilane, and vinyl diisopropoxysilane, and vinyl alkoxysilane having one alkoxy group bonded to a silicon atom, such as vinyl monomethoxysilane, vinyl monoethoxysilane, and vinyl monoisopropoxysilane. Only one type of the vinyl alkoxysilane may be used alone, or two or more types thereof may be used in combination.

Examples of the vinyl acetoxysilane include vinyl triacetoxysilane, vinyl diacetoxysilane, and vinyl monoacetoxysilane.

The component (F), from the viewpoint of the solder heat resistance, the crack resistance, and pressure cooker resistance (PCT resistance), may include barium sulfate. The component (F), from the viewpoint of improving an effect of preventing aggregation, may include alumina.

The average particle size of the component (F) may be 0.1 to 20 μm, 0.1 to 10 μm, 0.1 to 5 μm, or 0.1 to 1 μm. In a case where the average particle size is 20 μm or less, it is possible to further suppress a decrease in the insulation reliability of the permanent resist.

The content of the component (F) may be 10 to 80% by mass, 15 to 70% by mass, 20 to 60% by mass, 25 to 50% by mass, or 30 to 45% by mass, on the basis of the total solid content of the photosensitive resin composition. In a case where the content of the component (F) is in the range described above, it is possible to further improve the resolution of the photosensitive resin composition, and further improve the strength, the heat resistance, the insulation reliability, and the crack resistance of the permanent resist. From the same viewpoint, the content of the component (F) may be 10% by mass or more, 15% by mass or more, 20% by mass or more, 25% by mass or more, or 30% by mass or more, and may be 80% by mass or less, 70% by mass or less, 60% by mass or less, 50% by mass or less, or 45% by mass or less.

The content of the vinyl group-containing silica filler may be 5 to 60% by mass, 15 to 55% by mass, 20 to 50% by mass, or 25 to 45% by mass, on the basis of the total solid content of the photosensitive resin composition. In a case where the content of the vinyl group-containing silica filler is in the range described above, it is possible to further improve the developing property and the resolution of the photosensitive resin composition, and the crack resistance of the permanent resist. From the same viewpoint, the content of the vinyl group-containing silica filler may be 5% by mass or more, 15% by mass or more, 20% by mass or more, or 25% by mass or more, and may be 60% by mass or less, 55% by mass or less, 50% by mass or less, or 45% by mass or less.

The content of the vinyl group-containing silica filler in the component (F), from the viewpoint of the developing property, the resolution, and the crack resistance, may be 50 to 100% by mass, 55 to 100% by mass, 60 to 100% by mass, or 65 to 100% by mass, on the basis of the total amount of the component (F).

In the case of using the barium sulfate as the component (F), the content of the barium sulfate may be 5 to 30% by mass, 5 to 25% by mass, or 5 to 20% by mass, on the basis of the total solid content of the photosensitive resin composition. In a case where the content of the barium sulfate is in the range described above, it is possible to further improve the solder heat resistance and the PCT resistance.

### <Component (G): Curing Agent>

The photosensitive resin composition according to the present embodiment may further contain a curing agent as a component (G). Examples of the component (G) include a compound cured itself by heat, an ultraviolet ray, or the like, or a compound cured by a reaction with the carboxy group or the hydroxyl group of the component (A) by heat, an ultraviolet ray, or the like. By using the curing agent, it is possible to improve the heat resistance, the adhesiveness, the chemical resistance, and the like of the permanent resist.

Examples of the component (G) include a thermosetting compound such as a melamine compound and an oxazoline compound. Examples of the melamine compound include triaminotriazine, hexamethoxymelamine, and hexabutoxylated melamine. Only one type of the component (G) can be used alone, or two or more types thereof can be used in combination.

In the case of using the component (G), the content thereof may be 2 to 40% by mass, 3 to 30% by mass, or 5 to 20% by mass, on the basis of the total solid content of the photosensitive resin composition. In a case where the content of the component (G) is in the range described above, it is possible to further improve the heat resistance of the permanent resist to be formed, while maintaining a more excellent developing property.

In order to further improve the property of the permanent resist, such as the heat resistance, the adhesiveness, and the chemical resistance, in the photosensitive resin composition according to the present embodiment, a curing accelerator for accelerating the curing of the component (D) may be used together.

Examples of the curing accelerator include an imidazole derivative such as 2-methyl imidazole, 2-ethyl-4-methyl imidazole, 1-benzyl-2-methyl imidazole, 2-phenyl imidazole, and 2-phenyl-4-methyl-5-hydroxymethyl imidazole; guanamines such as acetoguanamine and benzoguanamine; polyamine such as diaminodiphenyl methane, m-phenylene diamine, m-xylene diamine, diaminodiphenyl sulfone, dicyan diamide, urea, a urea derivative, melamine, and polybasic hydrazide; organic acid salts or epoxy adducts thereof; an amine complex such as boron trifluoride; and a triazine derivative such as ethyl diamino-S-triazine, 2,4-diamino-S-triazine, and 2,4-diamino-6-xylyl-S-triazine. Only one type of the curing accelerator can be used alone, or two or more types thereof can be used in combination.

In the case of using the curing accelerator, the content thereof, from the viewpoint of improving reliability, may be 0.01 to 20% by mass, or 0.1 to 10% by mass, on the basis of the total solid content of the photosensitive resin composition.

### <Component (H): Elastomer>

The photosensitive resin composition according to the present embodiment may further contain an elastomer as a component (H). The component (H) may be used in a case where the photosensitive resin composition according to the present embodiment is used for a semiconductor package substrate. By adding the component (H) to the photosensitive resin composition, it is possible to suppress a decrease in flexibility and adhesive strength caused by strain (an internal stress) in the resin due to the curing shrinkage of the component (A). That is, it is possible to improve the flexibility and the adhesive strength of the permanent resist formed by the photosensitive resin composition.

Examples of the component (H) include a thermoplastic elastomer such as a styrene-based elastomer, an olefin-based elastomer, a urethane-based elastomer, a polyester-based elastomer, a polyamide-based elastomer, an acrylic elastomer, and a silicone-based elastomer. The thermoplastic elastomer is composed of a hard segment component contributing to the heat resistance and the strength, and a soft segment component contributing to ductility and toughness. Only one type of the component (H) can be used alone, or two or more types thereof can be used in combination.

As the urethane-based elastomer, a compound configured of a hard segment formed from low-molecular-weight (short-chain) diol and diisocyanate, and a soft segment formed from high-molecular-weight (long-chain) diol and diisocyanate can be used. Examples of the low-molecular-weight diol include ethylene glycol, propylene glycol, 1,4-butane diol, and bisphenol A. Examples of the high-molecular-weight diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate).

The number average molecular weight (Mn) of the low-molecular-weight diol may be 48 to 500. Mn of the high-molecular-weight diol may be 500 to 10000. As the urethane elastomer, for example, PANDEX T-2185 and T-2983N (manufactured by DIC Corporation), and Miractran E790 (manufactured by Nippon Miractran Company Limited) are commercially available.

As the polyester-based elastomer, a compound obtained by polycondensation between a dicarboxylic acid or a derivative thereof and a diol compound or a derivative thereof can be used. Examples of the dicarboxylic acid include an aromatic dicarboxylic acid such as a terephthalic acid, an isophthalic acid, and a naphthalene dicarboxylic acid, and an aromatic dicarboxylic acid in which a hydrogen atom in the aromatic nucleus of the aromatic dicarboxylic acid described above is substituted with a methyl group, an ethyl group, a phenyl group, or the like; an aliphatic dicarboxylic acid having 2 to 20 carbon atoms, such as an adipic acid, a sebacic acid, and a dodecane dicarboxylic acid; and an alicyclic dicarboxylic acid such as a cyclohexane dicarboxylic acid.

Examples of the diol compound include aliphatic diol or alicyclic diol such as ethylene glycol, 1,3-propane diol, 1,4-butane diol, 1,6-hexane diol, 1,10-decane diol, and 1,4-cyclohexane diol, and divalent phenol represented by Formula (IV) described below.

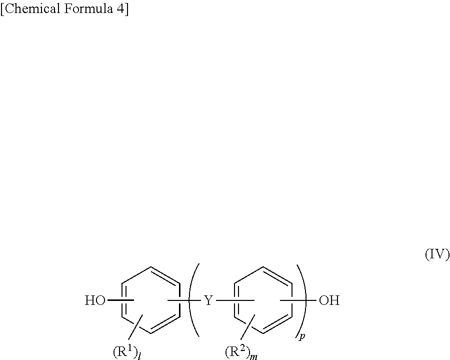

In Formula (IV), Y indicates an alkylene group having 1 to 10 carbon atoms, a cycloalkylene group having 4 to 8 carbon atoms, an ether group, a thioether group, a sulfonyl group, or a single bond, R¹ and R² each independently indicate a hydrogen atom, a halogen atom, or an alkyl group having 1 to 12 carbon atoms, 1 and m are each independently an integer of 0 to 4, and p is 0 or 1. The alkylene group and the cycloalkylene group may be linear or branched, and may be substituted with a halogen atom, an alkyl group, an aryl group, an aralkyl group, an amino group, an amide group, an alkoxy group, or the like.

Examples of the divalent phenol represented by Formula (IV) include bisphenol A, bis-(4-hydroxyphenyl) methane, bis-(4-hydroxy-3-methyl phenyl) propane, and resorcine. Only one type of the compound can be used alone, or two or more types thereof can be used in combination.

As the polyester-based elastomer, a multiblock copolymer in which an aromatic polyester (for example, polybutylene terephthalate) part is used for a hard segment component, and an aliphatic polyester (for example, polytetramethylene glycol) part is used for a soft segment component can be used. There are various grades of polyester-based elastomers, in accordance with a difference in the type, the ratio, and the molecular weight of the hard segment and the soft segment. As the polyester-based elastomer, for example, Hytrel (manufactured by DU PONT-TORAY CO., LTD., “Hytrel” is Registered Trademark), PELPRENE (manufactured by TOYOBO CO., LTD., “PELPRENE” is Registered Trademark), and Espel (manufactured by Showa Denko Materials Co., Ltd., “Espel” is Registered Trademark) are commercially available.

As the acrylic elastomer, a compound containing a constitutional unit based on acrylic acid ester as a main component can be used. Examples of the acrylic acid ester include ethyl acrylate, butyl acrylate, methoxyethyl acrylate, and ethoxyethyl acrylate. The acrylic elastomer may be a compound in which acrylic acid ester and acrylonitrile are copolymerized, or may be a compound in which a monomer having a functional group to be a cross-linking point is further copolymerized. Examples of the monomer having a functional group include glycidyl methacrylate and allyl glycidyl ether. Examples of the acrylic elastomer include an acrylonitrile-butyl acrylate copolymer, an acrylonitrile-butyl acrylate-ethyl acrylate copolymer, and an acrylonitrile-butyl acrylate-glycidyl methacrylate copolymer.

As an elastomer other than the thermoplastic elastomer, a rubber-modified epoxy resin may be used. The rubber-modified epoxy resin, for example, is obtained by modifying a part or all of the epoxy groups in the bisphenol F-type epoxy resin, the bisphenol A-type epoxy resin, the salicyl aldehyde-type epoxy resin, the phenol novolac-type epoxy resin, or the cresol novolac-type epoxy resin described above, with dual-end carboxylic acid-modified-type butadiene-acrylonitrile rubber, end amino-modified silicone rubber, or the like. Among such elastomers, from the viewpoint of shear adhesive strength, a dual-end carboxy group-modified butadiene-acrylonitrile copolymer, and Espel (manufactured by Showa Denko Materials Co., Ltd., Espel 1612 and 1620), which is a polyester-based elastomer having a hydroxyl group, may be used.

The content of the component (H) may be 2 to 40 parts by mass, 4 to 30 parts by mass, 10 to 25 parts by mass, or 15 to 22 parts by mass, with respect to 100 parts by mass of the component (A). In a case where the content of the component (H) is in the range described above, there is a tendency that an unexposed portion of a photosensitive layer is more likely to be eluted by the developer, and the elastic modulus of the permanent resist in a high temperature region is further decreases.

### <Other Components>

In order to adjust a viscosity, the photosensitive resin composition according to the present embodiment, as necessary, may be mixed with a diluent such as an organic solvent. Examples of the organic solvent include ketones such as methyl ethyl ketone and cyclohexanone, aromatic hydrocarbon such as toluene, xylene, and tetramethyl benzene, glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether, esters such as ethyl acetate, butyl acetate, butyl cellosolve acetate, and carbitol acetate, aliphatic hydrocarbon such as octane and decane, and a petroleum-based solvent such as petroleum ether, petroleum naphtha, hydrogenated petroleum naphtha, and solvent naphtha.

In the case of using the diluent, the content of the diluent in the photosensitive resin composition may be 10 to 50% by mass, 20 to 40% by mass, or 25 to 35% by mass. By setting the content of the diluent to be in the range described above, it is possible to improve the applicability of the photosensitive resin composition, and form a higher-definition pattern.

The photosensitive resin composition according to the present embodiment, as necessary, may be mixed with various additives. Examples of the additive include a polymerization inhibitor such as hydroquinone, methyl hydroquinone, hydroquinone monomethyl ether, catechol, and pyrogallol; a thickener such as bentone and montmorillonite; silicone-based, fluorine-based, and vinyl resin-based antifoaming agents; a silane coupling agent; and a flame retarder such as a brominated epoxy compound, an acid-modified brominated epoxy compound, an antimony compound, a phosphate compound of a phosphorus-based compound, aromatic condensed phosphoric acid ester, and halogen-containing condensed phosphoric acid ester.

The photosensitive resin composition according to the present embodiment can be prepared by homogeneously mixing each component described above with a roll mill, a bead mill, or the like.

### [Photosensitive Element]

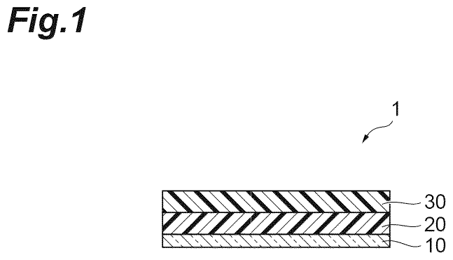

A photosensitive element according to the present embodiment includes a support film, and a photosensitive layer containing the photosensitive resin composition described above. FIG. 1 is a cross-sectional view schematically illustrating the photosensitive element according to the present embodiment. As illustrated in FIG. 1, a photosensitive element 1 includes a support film 10, and a photosensitive layer 20 formed on the support film 10.

The photosensitive element 1, for example, can be produced by applying the photosensitive resin composition according to the present embodiment onto the support film 10 with a known method such as reverse roll coating, gravure roll coating, comma coating, and curtain coating, and then, drying the coated film to form the photosensitive layer 20.

Examples of the support film include a polyester film such as polyethylene terephthalate and polybutylene terephthalate, and a polyolefin film such as polypropylene and polyethylene. The thickness of the support film, for example, may be 5 to 100 μm. The thickness of the photosensitive layer, for example, may be 10 to 50 μm, 15 to 40 μm, or 20 to 30 μm.

The coated film can be dried by using hot-air drying, and drying using a far infrared ray or a near infrared ray. A drying temperature may be 60 to 120° C., 70 to 110° C., or 80 to 100° C. A drying time may be 1 to 60 minutes, 2 to 30 minutes, or 5 to 20 minutes.

A protective film 30 covering the photosensitive layer 20 may be further provided on the photosensitive layer 20. In the photosensitive element 1, the protective film 30 can also be stacked on the surface of the photosensitive layer 20 on a side opposite to the surface in contact with the support film 10. As the protective film 30, for example, a polymer film such as polyethylene and polypropylene may be used. The protective film may be the same film as the support film, or may be a different film.

[Printed Wiring Board]

A printed wiring board according to the present embodiment includes a permanent resist including a cured product of the photosensitive resin composition according to the present embodiment. Since the printed wiring board according to the present embodiment includes the permanent resist including the cured product of the photosensitive resin composition according to the present embodiment, it is possible to reduce the occurrence of a crack in the permanent resist.

A method for producing a printed wiring board according to the present embodiment includes a step of forming a photosensitive layer on a substrate by using the photosensitive resin composition described above or the photosensitive element described above, a step of exposing and developing the photosensitive layer to form a resist pattern, and a step of curing the resist pattern to form a permanent resist. Hereinafter, an example of each step will be described.

First, as the substrate, a metal clad laminate such as a copper clad laminate is prepared, and the photosensitive layer is formed on the substrate. In the case of using the photosensitive resin composition, the photosensitive resin composition may be applied onto the substrate by a method such as a screen printing method, a spray method, a roll coating method, a curtain coating method, and an electrostatic coating method, and the formed coated film may be dried at 60 to 110° C. to form the photosensitive layer. The thickness of the coated film may be 10 to 200 μm, 15 to 150 μm, 20 to 100 μm, or 23 to 50 μm. In the case of using the photosensitive element, the photosensitive layer of the photosensitive element may be thermally laminated on the substrate by a laminator to form the photosensitive layer.

Next, a negative mask is brought into contact with the photosensitive layer directly or via a transparent film such as a support film, and irradiated with an active ray to be exposed, and then, an unexposed portion is dissolved and removed with a developer to form the resist pattern. Examples of the active ray include an electron beam, an ultraviolet ray, an X-ray, and the like, and the ultraviolet ray is preferable. As a light source, a low-pressure mercury lamp, a high-pressure mercury lamp, a super high-pressure mercury lamp, a halogen lamp, and the like can be used. An exposure amount may be 10 to 2000 mJ/cm², 100 to 1500 mJ/cm², or 300 to 1000 mJ/cm². Examples of a developing method include a dipping method and a spray method. As the developer, for example, an alkaline aqueous solution such as potassium hydroxide, sodium hydroxide, sodium carbonate, potassium carbonate, and tetramethyl ammonium hydroxide can be used.

Next, by performing at least one treatment of postexposure and postheating on the formed resist pattern, it is possible to sufficiently cure the resist pattern, and form the permanent resist. The exposure amount of the postexposure may be 100 to 5000 mJ/cm², 500 to 2000 mJ/cm², or 700 to 1500 mJ/cm². The heating temperature of the postheating may be 100 to 200° C., 120 to 180° C., or 135 to 165° C. The heating time of the postheating may be 5 minutes to 12 hours, 10 minutes to 6 hours, or 30 minutes to 2 hours. The thickness of the permanent resist may be 10 to 50 μm, 15 to 40 μm, or 20 to 30 μm. After that, wiring is formed by etching, and the printed wiring board is produced.

A permanent resist according to the present embodiment can be used as an interlayer dielectric layer or a surface protective layer of a semiconductor element. It is possible to produce the semiconductor element including the interlayer dielectric layer or the surface protective layer formed from the cured film of the photosensitive resin composition described above, and an electronic device including the semiconductor element. The semiconductor element, for example, may be a memory, a package, or the like, which has a multilayer wiring structure, a redistribution structure, and the like. Examples of the electronic device include a mobile phone, a smart phone, a tablet terminal, a personal computer, and a hard disk suspension. By including the pattern cured film formed by the photosensitive resin composition according to the present embodiment, it is possible to provide the semiconductor element and the electronic device excellent in the reliability.

### EXAMPLES

Hereinafter, the present disclosure will be described in more detail by Examples, but the present disclosure is not limited to such Examples.

### Synthesis Example 1

350 parts by mass of a bisphenol F novolac-type epoxy resin (Product Name: EXA-7376; manufactured by DIC Corporation; a bisphenol F novolac-type epoxy resin having a structure in which in Formula (I), Y¹ and Y² are a glycidyl group, and R¹¹ is a hydrogen atom; Epoxy Equivalent: 186 g/eq), 70 parts by mass of an acrylic acid, 0.5 parts by mass of methyl hydroquinone, and 120 parts by mass of carbitol acetate were prepared in a flask provided with a stirrer, a reflux condenser, and a thermometer, and stirred at 90° C. to completely dissolve the mixture. Next, the obtained solution was cooled to 60° C., and 2 parts by mass of triphenyl phosphine was added, heated to 100° C. to cause a reaction until the acid value of the solution was 1 mgKOH/g or less. 98 parts by mass of a tetrahydrophthalic anhydride (THPAC) and 85 parts by mass of carbitol acetate were added to the solution after the reaction to cause a reaction at 80° C. for 6 hours. After that, cooling was performed to a room temperature, a solution of THPAC-modified bisphenol F novolac-type epoxy acrylate (Solid Content Acid Value: 50.0 mgKOH/g; Solid Content Concentration: 73% by mass), which is a component (A), was obtained.

### [Photosensitive Resin Composition]

Each component was blended in accordance with a blending amount shown in Tables 1 and 2, and kneaded with a three-roll mill. After that, carbitol acetate was added such that a solid content concentration was 70% by mass to obtain a photosensitive resin composition. Tables 1 and 2 show the part by mass of the solid content of a component (A) to a component (F), based on the total solid content of the photosensitive resin composition.

The details of each component in Tables 1 and 2 are as described below.
A-1: an acid-modified vinyl group-containing resin obtained in Synthesis Example 1
A-2: an acid-modified vinyl group-containing resin obtained by acrylating a glycidyl group of a novolac-type epoxy resin having a structure in which in Formula (III′), R¹³ was a hydrogen atom, and Y⁵ was a glycidyl group (Product Name: UE-EXP-3165; manufactured by DIC Corporation), and modifying a hydroxyl group with a tetrahydrophthalic anhydride (Acid Value: 42.4 mgKOH/g)
B-1: a bisphenol A-type epoxy resin (Product Name: YD-8125; manufactured by NIPPON STEEL Chemical & Material Co., Ltd.; Epoxy Equivalent: 173 g/eq)
B-2: a novolac-type polyfunctional epoxy resin (Product Name: RE-306; manufactured by Nippon Kayaku Co., Ltd.; Epoxy Equivalent: 270 g/eq)
B-3: a bisphenol A-type novolac epoxy resin (Product Name: jER157S70; manufactured by Mitsubishi Chemical Corporation; Epoxy Equivalent: 210 g/eq)
B-4: a bisphenol F-type epoxy resin (Product Name: EXA-9580; manufactured by DIC Corporation; Epoxy Equivalent: 360 g/eq)
B-5: a tetrafunctional epoxy resin (Product Name: jER1031S; manufactured by Mitsubishi Chemical Corporation; Epoxy Equivalent: 200 g/eq)
C-1: 2-methyl-1-[4-(methyl thio)phenyl]-2-morpholino-1-propanone (Product Name: Irgacure 907; manufactured by BASF)
C-2: 2,4-diethyl thioxanthone (Product Name: DETX-S; manufactured by Nippon Kayaku Co., Ltd.)
D-1: dipentaerythritol hexaacrylate (Product Name: DPHA; manufactured by Nippon Kayaku Co., Ltd.)
E-1: a phthalocyanine-based pigment (Product Name: C.I.Pigment Blue 15; manufactured by SANYO COLOR WORKS, Ltd.)
F-1: barium sulfate particles (Product Name: B34; manufactured by SAKAI CHEMICAL INDUSTRY CO., LTD.; Average Particle Size: 0.3 μm)
F-2: a silica filler having a vinyl group derived from a vinyl silane compound obtained by adding 1 g of 1% by mass of vinyl trimethoxysilane (Product Name: KBM-1003; manufactured by Shin-Etsu Silicone Co., Ltd.) to 100 g of untreated silica particles (Product Name: SO-C2; manufactured by ADMATECHS COMPANY LIMITED, Average Particle Size: 0.5 μm), and performing stirring at 80° C. for 30 minutes
F-3: a silica filler having an epoxy group, obtained as with F-2, except that the vinyl trimethoxysilane was changed to 3-glycidoxypropyl trimethoxysilane (Product Name: KBM-403; manufactured by Shin-Etsu Silicone Co., Ltd.)
F-4: a silica filler having a methacryloyl group, obtained as with F-2, except that the vinyl trimethoxysilane was changed to 3-methacryloxypropyl methyl dimethoxysilane (Product Name: KBM-502; manufactured by Shin-Etsu Silicone Co., Ltd.)
F-5: a silica filler having a phenyl amino group, obtained as with F-2, except that the vinyl trimethoxysilane was changed to N-phenyl-3-aminopropyl trimethoxysilane (Product Name: KBM-573; manufactured by Shin-Etsu Silicone Co., Ltd.)
F-6: untreated silica particles (Product Name: SO-C2; manufactured by ADMATECHS COMPANY LIMITED, Average Particle Size: 0.5 μm)

An equivalent ratio shown in Tables 1 and 2, that is, an equivalent ratio of an epoxy group contained in the component (B) to a carboxy group contained in the component (A) was calculated by calculating the amount of carboxy group in the component (A) and the amount of epoxy in the component (B), respectively, as described below.

Amount (mmol) of Carboxy Group=Parts by Mass (g) of Component(A)×Acid Value(mgKOH/g) of Component(A)/Molecular Weight of KOH

$$Amount ( mmol ) of Epoxy Group = Parts by Mass ( g ) of Component ( B ) / Epoxy Equivalent ( g / eq ) of Component ( B ) \times 1000$$

In the case of using Example 1 as an example, since the part by mass (the solid content) of the component (A) was 26.9 (g), the acid value (the solid content) of the component (A) was 50 (mgKOH/g), and the molecular weight of the KOH was 56.11, the amount of carboxy group of the component (A) was 26.9×50/56.11=23.97 (mmol). Since the part by mass (the solid content) of the component (B) was 6.2 g, and the epoxy equivalent of the component (B) was 173 g/eq, the amount of epoxy group of the component (B) was 6.2/173×1000=35.84 (mmol). Accordingly, in Example 1, the equivalent ratio of the epoxy group in the component (B) to the carboxy group in the component (A) was 1.50.

By using the photosensitive resin composition, each evaluation was performed in the following condition. Results are shown in Tables 1 and 2.

### (Production of Test Piece 1)

The photosensitive resin compositions of Examples and Comparative Examples were applied onto a copper clad laminate (a copper clad laminate including a copper foil disposed on a glass epoxy material, manufactured by Showa Denko Materials Co., Ltd., Product Name: MCL-E-67) with a thickness of 0.6 mm by a screen printing method such that the thickness after drying was 35 μm, and then, dried at 80° C. for 20 minutes by using a hot-air circulation drier to form photosensitive layers. Next, a negative mask having a predetermined pattern adhered tightly to the obtained photosensitive layer, and was exposed in an exposure amount of 600 mJ/cm² by using an ultraviolet ray exposure machine. After that, spray development was performed with 1% by mass of a sodium carbonate aqueous solution at a pressure of 1.765×10⁵ Pa for 60 seconds, and an unexposed portion was dissolved and developed. Next, exposure was performed in an exposure amount of 1000 mJ/cm² by using an ultraviolet ray exposure machine, and heating was performed at 150° C. for 1 hour to produce a test piece 1 having a permanent resist.

### (Crack Resistance)

For the test piece 1, a temperature cycle test was performed at −65° C. for 30 minutes and at 150° C. for 30 minutes as 1 cycle, the permanent resist was observed visually and with an optical microscope at the time point of 1000 cycles, 2000 cycles, and 3000 cycles, and crack resistance was evaluated in accordance with the following criteria.
S: the occurrence of a crack was not checked at 3000 cycles.
A: the occurrence of a crack was not checked at 2000 cycles, but the occurrence of a crack was checked at 3000 cycles.
B: the occurrence of a crack was not checked at 1000 cycles, but the occurrence of a crack was checked at 2000 cycles.
C: the occurrence of a crack was checked at 1000 cycles.

### (Developing Property)

The photosensitive resin compositions of Examples and Comparative Examples were applied to a copper clad laminate (manufactured by Showa Denko Materials Co., Ltd., Product Name: MCL-E-67) by a screen printing method such that the thickness after drying was 15 μm, and then, dried at 75° C. for 30 minutes by using a hot-air circulation drier to form photosensitive layers. Next, the obtained photosensitive layer was irradiated with an ultraviolet ray in an accumulated exposure amount of 100 mJ/cm² via a negative mask in which non-light transmissive portions with a diameter of 80 μm were scattered in an area of 1×1 cm square. After that, spray development was performed with 1% by mass of a sodium carbonate aqueous solution at a pressure of 1.8 kgf/cm² for 60 seconds, and an unexposed portion was dissolved and developed to produce a test piece 2. After that, an opening portion of the test piece 2 was observed with SEM (manufactured by High-Tech Corporation, Model Number: S4200, a field emission scanning electron microscope) at a magnification of 10000 times, and on the basis of the remaining state of the resist residue, a developing property was evaluated in accordance with the following criteria.
S: there were 0 residues in one field of view.
A: there were 1 or more and less than 5 residues in one field of view.
B: there were 5 or more and less than 10 residues in one field of view.
C: there were 10 or more residues in one field of view.

### (Resolution)

A test piece 3 having a cured film in which an opening pattern with a predetermined size was formed was produced as with the test piece 1, except that as the negative mask, a negative mask having an opening pattern with a predetermined size (Opening Diameter Size: 30, 40, 50, 60, 70, 80, 90, 100, 110, 120, 150, and 200 μm) was used. The test piece 3 was observed with an optical microscope, and resolution was evaluated in accordance with the following criteria.
A: the minimum mask opening diameter was 35 μm or less.
B: the minimum mask opening diameter was greater than 35 μm and 55 μm or less.
C: the minimum mask opening diameter was greater than 55 μm.

### (Solder Heat Resistance)

Water-soluble flux was applied to the test piece 1, and the test piece was dipped in a solder bath at 265° C. for 10 seconds. This was set as 1 cycle, and 6 cycles were repeated, and then, the appearance of the permanent resist was visually observed, and solder heat resistance was evaluated in accordance with the following criteria.
A: there was no appearance change in the permanent resist of 30 cm×30 cm.
B: there were 1 to 5 floats or blisters of the coated film in the permanent resist of 30 cm×30 cm.
C: there were 6 or more floats or blisters of the coated film in the permanent resist of 30 cm×30 cm.

### (Solvent Resistance)

The test piece 1 was dipped in isopropyl alcohol at a room temperature for 30 minutes, and whether there was an abnormality in the appearance of the permanent resist was checked, and then, a peeling test was performed with a cellophane tape. Solvent resistance was evaluated in accordance with the following criteria.
A: there was no abnormality in the appearance of the permanent resist, and peeling did not occur.
B: there was a slight change in the appearance of the permanent resist.
C: there was an abnormality in the appearance of the permanent resist, or peeling occurred.

### (Acid Resistance)

The test piece 1 was dipped in 10% by mass of a hydrochloric acid aqueous solution at a room temperature for 30 minutes, and whether there was an abnormality in the appearance of the permanent resist was checked, and then, a peeling test was performed with a cellophane tape. Acid resistance was evaluated in accordance with the following criteria.
A: there was no abnormality in the appearance of the permanent resist, and peeling did not occur.
B: there was a slight change in the appearance of the permanent resist.
C: there was an abnormality in the appearance of the permanent resist, or peeling occurred.

### (Alkali Resistance)

The test piece 1 was dipped in 5% by mass of a sodium hydroxide aqueous solution at a room temperature for 30 minutes, and whether there was an abnormality in the appearance of the permanent resist was checked, and then, a peeling test was performed with a cellophane tape. Alkali resistance was evaluated in accordance with the following criteria.
A: there was no abnormality in the appearance of the permanent resist, and peeling did not occur.
B: there was a slight change in the appearance of the permanent resist.
C: there was an abnormality in the appearance of the permanent resist, or peeling occurred.

### (Electrical Insulating Property)

A test piece 4 was formed as with the test piece 1, except that a bismaleimide triazine substrate in which a comb-shaped electrode (Line/Space=10 μm/10 μm) was formed was used instead of the copper clad laminate. Next, the test piece 4 was exposed to a condition of 135° C., 85%, and 5 V. After that, the degree of migration that occurred in the permanent resist was observed with a metallographic microscope at a magnification of 100 times, and an electrical insulating property was evaluated in accordance with the following criteria.
A: it was found that migration did not occur in the permanent resist and a resistance value did not decrease to 10⁻⁶Ω or less even more than 200 hours.
B: it was found that for 100 hours or longer and shorter than 200 hours migration did not occur in the permanent resist and a resistance value did not decrease to 10⁻⁶Ω or less.
C: it was found that less than 100 hours migration occurred in the permanent resist and a resistance value decreased to 10⁻⁶Ω or less.

TABLE 1

| Example | | 1 | 2 | 3 | 4 | 5 | 6 | 7 | 8 | 9 | 10 | 11 | 12 | 13 |
|---|---|---|---|---|---|---|---|---|---|---|---|---|---|---|
| (A) | A-1 | 26.90 | 26.90 | 26.90 | 26.90 | — | 18.83 | 26.90 | 26.90 | 26.90 | 26.90 | 26.90 | 26.90 | 26.90 |
| | A-2 | — | — | — | — | 26.90 | 8.07 | — | — | — | — | — | — | — |
| (B) | B-1 | 6.20 | 8.29 | 10.35 | 16.57 | 14.05 | 15.84 | 29.03 | — | — | — | — | — | 16.57 |
| | B-2 | — | — | — | — | — | — | — | 25.83 | — | — | — | 9.89 | — |
| | B-3 | — | — | — | — | — | — | — | — | 20.10 | — | — | — | — |
| | B-4 | — | — | — | — | — | — | — | — | — | 34.50 | — | 21.32 | — |
| | B-5 | — | — | — | — | — | — | — | — | — | — | 19.16 | — | — |
| (C) | C-1 | 0.77 | 0.77 | 0.77 | 0.77 | 0.77 | 0.77 | 0.77 | 0.77 | 0.77 | 0.77 | 0.77 | 0.77 | 0.77 |
| | C-2 | 0.04 | 0.04 | 0.04 | 0.04 | 0.04 | 0.04 | 0.04 | 0.04 | 0.04 | 0.04 | 0.04 | 0.04 | 0.04 |
| (D) | D-1 | 5.30 | 5.30 | 5.30 | 5.30 | 5.30 | 5.30 | 5.30 | 5.30 | 5.30 | 5.30 | 5.30 | 5.30 | 5.30 |
| (E) | E-1 | 3.05 | 3.05 | 3.05 | 3.05 | 3.05 | 3.05 | 3.05 | 3.05 | 3.05 | 3.05 | 3.05 | 3.05 | 3.05 |
| (F) | F-1 | 11.37 | 11.37 | 11.37 | 11.37 | 11.37 | 11.37 | 11.37 | 11.37 | 11.37 | 11.37 | 11.37 | 11.37 | — |
| | F-2 | 25.88 | 25.88 | 25.88 | 25.88 | 25.88 | 25.88 | 25.88 | 25.88 | 25.88 | 25.88 | 25.88 | 25.88 | 37.25 |

| | | | | | | | | | | | | | |
|---|---|---|---|---|---|---|---|---|---|---|---|---|---|
| Equivalent ratio | 1.50 | 2.00 | 2.50 | 4.00 | 4.00 | 4.00 | 7.00 | 4.00 | 4.00 | 4.00 | 4.00 | 4.00 | 4.00 |
| Crack resistance | B | A | S | S | S | S | S | S | S | S | S | S | S |
| Developing property | A | A | S | S | S | S | S | S | S | S | S | S | S |
| Resolution | A | A | A | A | A | A | A | A | A | A | A | A | A |
| Solder heat resistance | A | A | A | A | A | A | A | A | A | A | A | A | A |
| Solvent resistance | A | A | A | A | A | A | A | A | A | A | A | A | A |
| Acid resistance | A | A | A | A | A | A | A | A | A | A | A | A | A |
| Alkali resistance | A | A | A | A | A | A | A | A | A | A | A | A | A |
| Electrical insulating | B | A | A | A | A | A | A | A | A | A | A | A | A |
| property | | | | | | | | | | | | | |

TABLE 2

| Com- | | | | | | | | |
|---|---|---|---|---|---|---|---|---|
| parative | | | | | | | | |
| Example | | 1 | 2 | 3 | 4 | 5 | 6 | 7 |
| (A) | A-1 | 26.90 | 26.90 | 26.90 | 26.90 | 26.90 | 26.90 | 26.90 |
| (B) | B-1 | 4.15 | 33.18 | 16.57 | 16.57 | 16.57 | 16.57 | 16.57 |
| (C) | C-1 | 0.77 | 0.77 | 0.77 | 0.77 | 0.77 | 0.77 | 0.77 |
| | C-2 | 0.04 | 0.04 | 0.04 | 0.04 | 0.04 | 0.04 | 0.04 |
| (D) | D-1 | 5.30 | 5.30 | 5.30 | 5.30 | 5.30 | 5.30 | 5.30 |
| (E) | E-1 | 3.05 | 3.05 | 3.05 | 3.05 | 3.05 | 3.05 | 3.05 |
| (F) | F-1 | 11.37 | 11.37 | 11.37 | 11.37 | 11.37 | 11.37 | 37.25 |
| | F-2 | 25.88 | 25.88 | — | — | — | — | — |
| | F-3 | — | — | 25.88 | — | — | — | — |
| | F-4 | — | — | — | 25.88 | — | — | — |
| | F-5 | — | — | — | — | 25.88 | — | — |
| | F-6 | — | — | — | — | — | 25.88 | — |

| | | | | | | | |
|---|---|---|---|---|---|---|---|
| Equivalent | 1.00 | 8.00 | 4.00 | 4.00 | 4.00 | 4.00 | 4.00 |
| ratio | | | | | | | |
| Crack | C | A | A | A | A | C | C |
| resistance | | | | | | | |
| Developing | A | C | C | C | C | C | C |
| property | | | | | | | |
| Resolution | A | C | C | C | C | C | C |
| Solder heat | A | C | A | A | A | A | A |
| resistance | | | | | | | |
| Solvent | A | C | A | A | A | A | A |
| resistance | | | | | | | |
| Acid | A | C | A | A | A | A | A |
| resistance | | | | | | | |
| Alkali | A | C | A | A | A | A | A |
| resistance | | | | | | | |
| Electrical | C | A | A | A | A | A | A |
| insulating | | | | | | | |
| property | | | | | | | |

From Tables 1 and 2, it was checked that the photosensitive resin compositions of Examples were capable of forming the permanent resist excellent in the crack resistance, and were excellent in the developing property.

### [Photosensitive Element]

Each of the photosensitive resin compositions was diluted with methyl ethyl ketone, applied onto a polyethylene terephthalate (PET) film, and dried at 90° C. for 10 minutes to form a photosensitive layer with a thickness of 25 μm. By sticking a PET film as a protective film onto the photosensitive layer, a photosensitive element was produced.

Crack resistance, developing property, resolution, solder heat resistance, solvent resistance, acid resistance, alkali resistance, and electrical insulating property were evaluated by using the photosensitive layer of the photosensitive element, and the same results as the evaluation results in the case of using the photosensitive resin composition shown in Tables 1 and 2 were obtained. A test piece in the case of using the photosensitive layer was produced as with the test pieces 1 to 4, except that the protective film was peeled from the photosensitive element, the photosensitive layer of the photosensitive element was thermally laminated on the substrate, and then, the support film was peeled to form the photosensitive layer on the substrate.

### REFERENCE SIGNS LIST

1: photosensitive element, 10: support film, 20: photosensitive layer, 30: protective film.

1. A photosensitive resin composition for a permanent resist, comprising:
an acid-modified vinyl group-containing resin (A);
an epoxy compound (B);
a photopolymerization initiator (C);
a photopolymerizable compound (D); and
an inorganic filler (F),
wherein an equivalent ratio of an epoxy group contained in the epoxy compound (B) to a carboxy group contained in the acid-modified vinyl group-containing resin (A) is 1.25 to 7.50, and
the inorganic filler (F) includes a silica filler having a vinyl group derived from a vinyl silane compound.

2. The photosensitive resin composition according to claim 1,
wherein the equivalent ratio is 2.00 to 7.50.

3. The photosensitive resin composition according to claim 1,
wherein the equivalent ratio is 2.50 to 7.50.

4. The photosensitive resin composition according to claim 1, further comprising
a pigment (E).

5. A photosensitive element, comprising:
a support film; and
a photosensitive layer formed on the support film,
wherein the photosensitive layer contains the photosensitive resin composition according to claim 1.

6. A printed wiring board, comprising
a permanent resist including a cured product of the photosensitive resin composition according to claim 1.

7. The printed wiring board according to claim 6,
wherein a thickness of the permanent resist is 10 to 50 μm.

8. A method for producing a printed wiring board, comprising:
a step of forming a photosensitive layer on a substrate by using the photosensitive resin composition according to claim 1;
a step of exposing and developing the photosensitive layer to form a resist pattern; and
a step of curing the resist pattern to form a permanent resist.

9. A method for producing a printed wiring board, comprising:
a step of forming a photosensitive layer on a substrate by using the photosensitive element according to claim 5;
a step of exposing and developing the photosensitive layer to form a resist pattern; and
a step of curing the resist pattern to form a permanent resist.

10. The photosensitive resin composition according to claim 1, wherein a content of the silica filler having a vinyl group derived from a vinyl silane compound is 20% by mass or more, on the basis of the total solid content in the photosensitive resin composition.
